(19) United States
(12) Patent Application Publication
(10) Pub. No.: US 2025/0121735 A1
(43) Pub. Date: Apr. 17, 2025

(54) METHOD FOR DESIGNING ACCELERATED BATTERY AGING TESTING PROTOCOL FROM BATTERY ELECTRIC VEHICLE USAGE DATA

(71) Applicant: FCA US LLC, Auburn Hills, MI (US)

(72) Inventors: Satyam Panchal, Breslau (CA); Guang Chen, Auburn Hills, MI (US); Massimo Cancian, Rubiera (IT); Marcello Canova, Columbus, OH (US); Xiaoling Chen, Sterling Heights, MI (US); Faissal El Idrissi, Columbus, OH (US); Prashanth Ramesh, Columbus, OH (US)

(21) Appl. No.: 18/484,719

(22) Filed: Oct. 11, 2023

(51) Int. Cl. B60L 58/16; B60L 58/12; G01R 31/367; G01R 31/392; G07C 5/04

(52) U.S. Cl. CPC B60L 58/16; B60L 58/12; G01R 31/367; G01R 31/392; G07C 5/04

(57) ABSTRACT

A method for designing an accelerated battery aging testing protocol from battery electric vehicle usage data is provided. An initial search space database is created based on a collection of vehicle usage data. The usage data includes current demand over a first timeframe. Data compression is performed including classifying the database into specific segments representing use events. A synthetic profile is generated including a sequence of elements having a battery current and a battery state of charge (SOC) for selected segments of the specific segments. An optimization for accelerated aging of the battery is defined. A genetic algorithm (GA) is executed that generates the accelerated battery aging testing protocol requiring a second timeframe, shorter than the first timeframe, based on the optimization.

### FIELD

The present application generally relates to electrified vehicles and, more particularly, to a method for designing an accelerated battery aging testing protocol from battery electric vehicle usage data.

### BACKGROUND

An electrified vehicle (hybrid electric, plug-in hybrid electric, range-extended electric, battery electric, etc.) includes at least one battery system and at least one electric motor. Typically, the electrified vehicle would include a high voltage battery system and a low voltage (e.g., 12 volt) battery system. In such a configuration, the high voltage battery system is utilized to power at least one electric motor configured on the vehicle and to recharge the low voltage battery system via a direct current to direct current (DC-DC) converter.

Various testing procedures exist for evaluating battery performance and longevity. In many cases however the testing can take a long time. Thus, there is a need to develop accelerated testing procedures that accurately represent real world conditions while shortening the time cycle of the testing. Accordingly, while conventional battery testing procedures do work well for their intended purpose, there exists an opportunity for improvement in the relevant art.

### SUMMARY

According to one example aspect of the invention, a method for designing an accelerated battery aging testing protocol from battery electric vehicle usage data is provided. An initial search space database is created based on a collection of vehicle usage data. The usage data includes current demand over a first timeframe. Data compression is performed including classifying the database into specific segments representing use events. A synthetic profile is generated including a sequence of elements having a battery current and a battery state of charge (SOC) selected among the specific segments that have been previously sorted and classified. An optimization for accelerated aging of the battery is defined. A genetic algorithm (GA) is executed that generates the accelerated battery aging testing protocol requiring a second timeframe, shorter than the first timeframe, based on the optimization.

In some implementations, the segments are selected proportionally to an amount of time the battery electric vehicle is used in all use events, including but not limited to, driving, parking and charging. The synthetic profile is statistically representative of the initial search space database.

In some implementations, generating the synthetic profile for selected segments includes selecting segments representing high stress on the battery.

According to another example aspect of the invention, generating the synthetic profile for selected segments includes removing segments representing low stress on the battery.

In some implementations, generating the synthetic profile for selected segments includes selecting segments representative of driving conditions.

In some implementations, generating the synthetic profile for selected segments includes selecting segments representative of rural driving conditions.

In other features, generating the synthetic profile for selected segments includes selecting one of driving conditions and battery charging conditions.

In other implementations, defining an optimization includes leveraging prediction of degradation of the battery resulting from applying a synthetic current sequence to a battery model.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having a battery system according to the principles of the present application;

FIG. 2 is a flow chart representing a method for designing an accelerated battery aging testing protocol from battery electric vehicle usage data;

FIG. 3A illustrates an exemplary resulting current profile;

FIG. 3B illustrates an exemplary state of charge (SOC) profile;

FIG. 4A illustrates an exemplary distribution of SOC values in the synthetic cycle;

FIG. 4B illustrates an exemplary distribution of SOC values from the initial dataset.

FIGS. 5A and 5B illustrate sample results from a Pareto analysis that was performed to explore the influence of a weight factor λ_{Γ} on the solution of a generic algorithm (GA);

FIG. 6A illustrates the current behavior in time domain for the initial candidate profile and after executing the GA optimization;

FIG. 6B illustrates the SOC behavior in time domain for the initial candidate profile and after executing the GA optimization;

FIG. 7A illustrates a distribution of SOC values using the original dataset;

FIG. 7B illustrates a distribution of SOC values after optimization;

FIG. 8A illustrates summaries of representative cycles generated using the GA based optimization algorithm showing distributions of capacity loss (%;

FIG. 8B illustrates summaries of representative cycles generated using the GA based optimization algorithm showing time duration of the profile; and

FIG. 8C illustrates summaries of representative cycles generated using the GA based optimization algorithm showing a similarity index quantified by test statistics.

### DESCRIPTION

Most of the procedures used in industry to test batteries for electrified vehicles utilize testing profiles that include temperatures and currents (as used herein, “current” is a current measured at the battery) that are typically quite severe compared to actual usage conditions seen by the battery when installed and utilized on electrified vehicles. These elevated temperatures and currents are solely aimed at accelerating the aging of the battery and completing the test in a reasonable amount of time. In examples, such conventional testing techniques apply a constant current to charge and discharge the battery repeatedly with a constant cycle (similar to mechanical fatigue). In this regard, such existing testing procedures subject a battery to a harsher condition than would be experienced in real world applications. The present disclosure provides a method for designing an accelerated battery aging testing protocol from battery electric vehicle usage data. In particular, the method seeks to quantify the rate at which batteries for electrified vehicles degrade in terms of performance while providing a testing procedure that requires a reduced time period to complete. Moreover, the method discussed herein, while requiring a reduced timeframe to complete, is representative of real world usage characteristics.

The method discussed herein creates a database with sample data from vehicles, or a fleet of vehicles. The database includes conditions representative of daily use including driving, parking, and charging. As used herein “conditions” means a collection of time sampled data that include (but not limited to) battery current and battery State of Charge (SOC). Using data manipulation and reduction techniques, the method creates a synthetic testing profile that contains all of the information that is in the original database representative of real world use. The method composes the synthetic testing cycle in a way that selects the portions of the datasets that are mostly relevant for characterizing the battery degradation. Knowledge of battery degradation requires knowledge of the effects of current/SOC/time on battery degradation. This can be accomplished either by exhaustive testing (prior art), or by leveraging physics-based models that predict cell performance and degradation in a simulated environment, as accomplished by this disclosure. A testing cycle composed according to the methods described herein is then constructed in a laboratory setting under controlled conditions that can stress the battery with the purpose of evaluating the durability of the battery while still being representative of the initial sample vehicle data in the database. In the example described herein, the database includes conditions representative of driving. However, the database can be extended to include parking, charging or combinations thereof within the scope of this disclosure, without modification to the method.

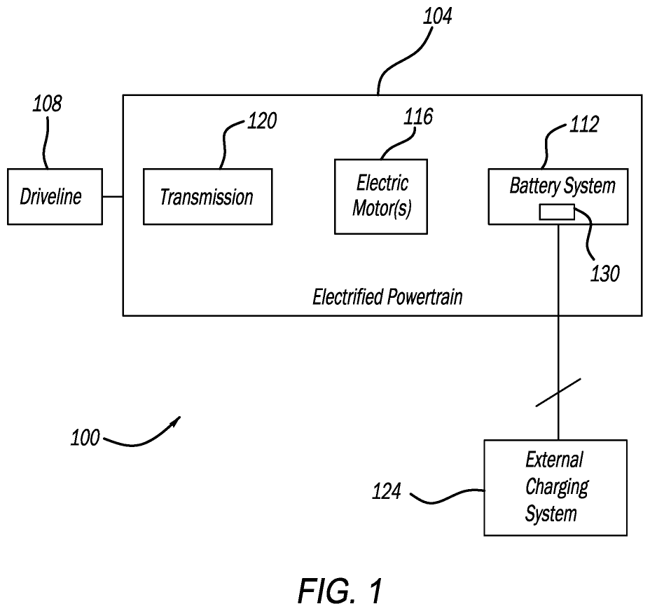

Referring now to FIG. 1, afunctional block diagram of an example electrified vehicle 100 (also referred to herein as “vehicle 100”) is illustrated. The vehicle 100 includes an electrified powertrain 104 configured to generate and transfer drive torque to a driveline 108 of the vehicle 100 for propulsion. The electrified powertrain 104 generally comprises a high voltage battery system 112 (also referred to herein as “battery system 112”), one or more electric motors 116, and a transmission 120. The battery system 112 is selectively connectable (e.g., by the driver) to an external charging system 124 (also referred to herein as “charger 124”) for charging of the battery system 112. The battery system 112 includes at least one battery pack assembly 130. The battery pack assembly 130 can be representative of a battery that is a candidate for the method of the present disclosure.

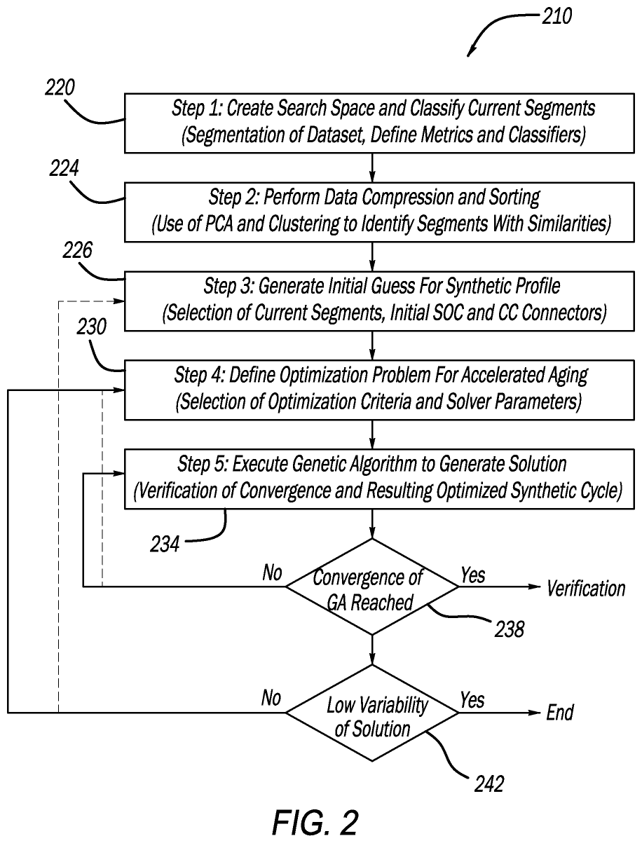

With additional reference now to FIG. 2, a method for designing an accelerated battery aging testing protocol from battery electric vehicle usage data according to an example of the present disclosure is shown and generally identified at reference numeral 210. At 220, a search space is created and segments are classified. In this regard, at 220 vehicle usage data is collected to create a database of current demand versus time (e.g., a year, a month or other defined timeframe of usage of a vehicle). Algorithms that include data reduction and classification are used to segment the data into specific events. As used herein, various algorithms can be executed by software used in computing systems. The events are analyzed based on metrics that are important for battery aging. For example, during a 5 hour use case, a vehicle drives in a rural setting (such as on a highway) for 2 hours and in an urban setting (such as in a city) for 3 hours. As expected, a rural setting is conducive of easy conditions including constant vehicle speeds without hard braking and accelerations whereas an urban setting includes harsher conditions including hard braking and hard accelerating. From the point of view of aging a battery, the urban setting will elevate battery degradation more than the rural setting. The data selection at 220 segments the driving data into smaller subsets that are analyzed to understand the characteristics of the current (minimum, maximum, average, etc.). A set of metrics and classifiers are labelled on each of the segments.

At 224, data compression and sorting are performed. Segments that share similarities in battery current in the metrics defined at 222 are identified and grouped. In other words, data is grouped based on current similarities instead of a time progression representing the order of a given drive. In examples, one group of data will include urban driving, another group of data will include rural driving, etc. In examples, algorithms, based on the classifiers developed at 222, reduce the amount of data (for example from many data points to only a few representative conditions). In examples, principal component analysis (PCA) is used to reduce the dimensionality of the feature matrix, which consists of a large number of interrelated variables. PCA manipulates a dataset by obtaining orthogonal vectors representing new, uncorrelated variables for the dataset, which are termed principal components. The principal component is a linear combination of the original features. These components are orthogonal, i.e., the correlation between any pair of principal components is zero. The importance of each component decreases, meaning that the first principal component captures the most variance of each attribute.

At 226, an initial guess for a synthetic profile is generated. Of the pool of segments of data, a cycle of fixed duration is created by selecting the segments of data representative of how the vehicle is driven in real world situations. For example, for selecting a test having one hour duration, a collection of available segments is chosen. The chosen segments are not selected only from one driving classification (e.g., urban driving), but rather segments are selected proportionally to an amount of time the vehicle is used in all settings (urban, rural, etc.). By choosing segments from multiple classifications, a real-world scenario can be simulated. The synthetic profile can be a sequence of elements. Each element of the sequence is defined by two variables: an index pointing to a driving current segment and an initial battery state of charge (SOC). To design the synthetic current profile, the segments are selected by picking among all the clusters created at 224. To start the process, an initial target duration of the profile is arbitrarily set.

From this input, an estimated total number of segments is obtained based on the average duration of all segments contained in all clusters. Knowing the probability distribution corresponding to the size of each cluster and the mean time duration of the current segments in each cluster, the mean time duration of a single current segment can be estimated. This allows one to compute the number of segments to be selected in the sequence. To make sure that the designed driving profile is representative of the original driving scenario, a probability vector of selecting the clusters is applied to ensure that the clusters containing more driving segments contribute more segments in the synthetic profile. The initial condition for the battery SOC corresponding to each segment is determined by creating a random variable, which is based on the statistical distribution obtained by processing representative usage data of a BEV over a given period of time.

A determination is made for each driving current segment and corresponding initial SOC value in the sequence. The resulting current profile can be modified to ensure SOC continuity. Because initial SOC values are selected from a probability density function, additional charging or discharging events can be inserted between adjacent driving current segments.

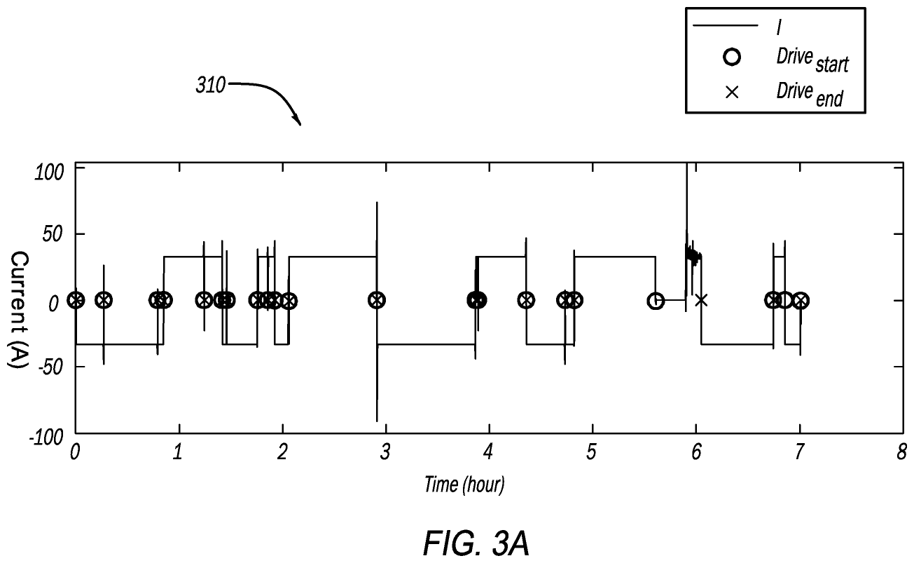

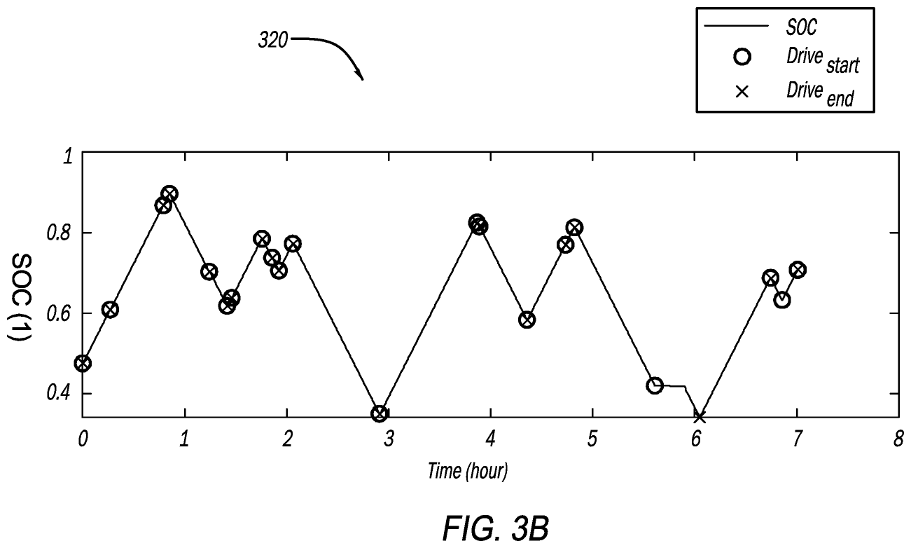

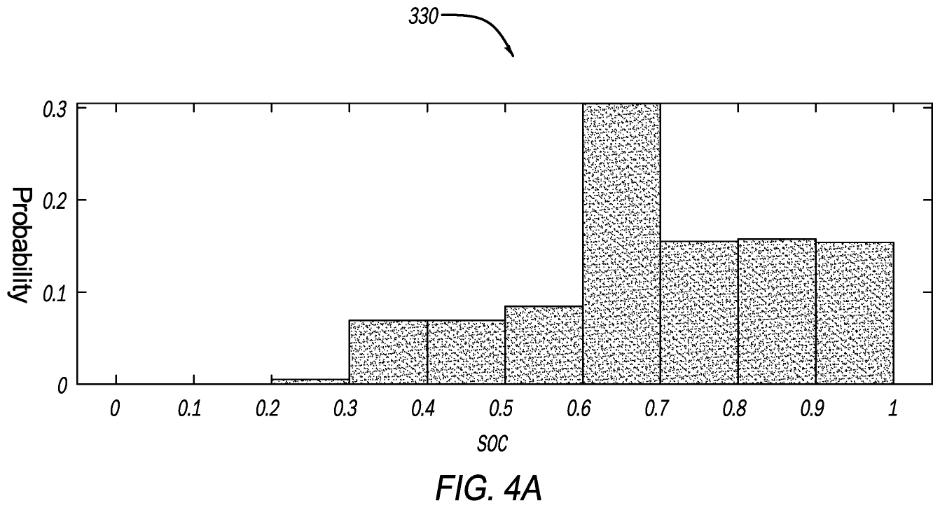

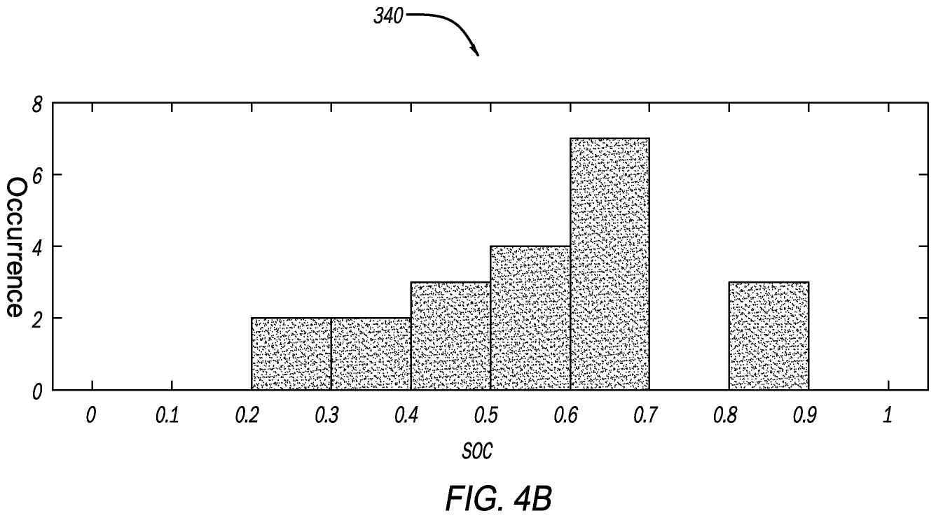

Turning to FIGS. 3A-4B, a sample synthetic cycle generated using an algorithm. The sample synthetic cycle was created by specifying 600 seconds of driving time (corresponding to roughly a 10 minute driving segment), while the constant current (CC) events are set at C/2. The resulting current profile 310, SOC profile 320, distribution of SOC values in the synthetic cycle 330 and distribution of SOC values from the initial dataset 340 are shown. As shown, the synthetic cycle produces a very similar distribution of SOC to the original dataset.

At 230, the optimization problem for accelerated aging is defined. Out of the segmented data, a synthetic cycle is selected that is representative of real world driving while accelerating the degradation of the battery. As explained above, steps 220, 224 and 226 creates a current/SOC profile that is statistically representative of the initial dataset. The profile can be used to run simulation studies of battery aging and predict the resulting cumulative degradation. Alternatively, it can be considered an initial guess to design a synthetic current profile of a fixed duration that accelerates battery aging. To this extent, an optimization problem can be defined by leveraging the prediction of cell degradation resulting from applying the synthetic current sequence to a battery model. This step requires an electrochemical model of a lithium-ion cell that contains a sub-model predicting the main degradation mechanism (such as SEI layer growth and loss of active material). A multi-objective optimization problem is formulated to trade-off the cumulative degradation applied to the battery cell (as computed by the simulation model) and the similarity of the synthetic current sequence to original dataset.

At 234 a genetic algorithm (GA) to generate a solution is executed. The optimization problem defined at 230 is large-scale, mixed-integer and nonlinear, requiring a gradient-free global optimization algorithm to obtain a solution. For this problem, the (GA) is utilized. In examples, the GA can be utilized based on software including a global optimization toolbox in MATLAB®. GA represents a family of search heuristics to find approximate global optimal solutions to constrained and unconstrained optimization problems and search problems. GA is based on a natural selection process that mimics biological evolution. The algorithm repeatedly modifies a population of individual solutions. At each step, the genetic algorithm selects individuals from the current population and uses them as parents to produce the children for the next generation. Over successive generations, the population “evolves” toward an optimal solution. GA is structured on three steps including initial population, creating the next generation and termination conditions.

The GA options and settings need to be properly tuned to the specific problem. To perform this calibration, the GA is repeatedly executed to evaluate the rate of convergence of the algorithm (which termination condition is reached) and the variability of the solution obtained. To initialize GA, an initial population is generated randomly based on the chosen option. Then, the initial guess from 226 is manually imposed (substituting one of the individuals in the initial population) to improve the convergence rate. In other examples, step 226 could be repeated multiple times to generate different initial candidate solutions.

Various methods can be used to improve consistency of the solution via multi-step GA. The large variability in the results produced by GA is caused by many factors including very large variable space to explore and objective function presenting multiple local minima. Different large-scale optimization methods (e.g., Monte Carlo Tree Search) could be explored to reduce the variability in the solution. Alternatively, a multi-step method could be applied to improve the consistency of the GA. The method includes 1) start from same initial guess, execute a “coarse GA” repeatedly for a high number of repetitions. Limit the number of generations to speed up termination of the algorithm (even if a sub-optimal solution is obtained); even though the results obtained will have high variability, select the best case based on objective function. 2) set the best case found in 1) as one of the initial population in the next exploration. 3) execute a “fine GA” from the initial condition determined in 2); increase the number of maximum iterations and reduce tolerances; reduce the number of repetitions to a minimum. By applying this method, the algorithm is able to converge more consistently, both in term of segment index and initial SOC value. While the multi-step method improves the consistency of the solution (i.e., GA will converge faster to the same solution), it will limit the exploration of the solution space, with risk of producing local minima.

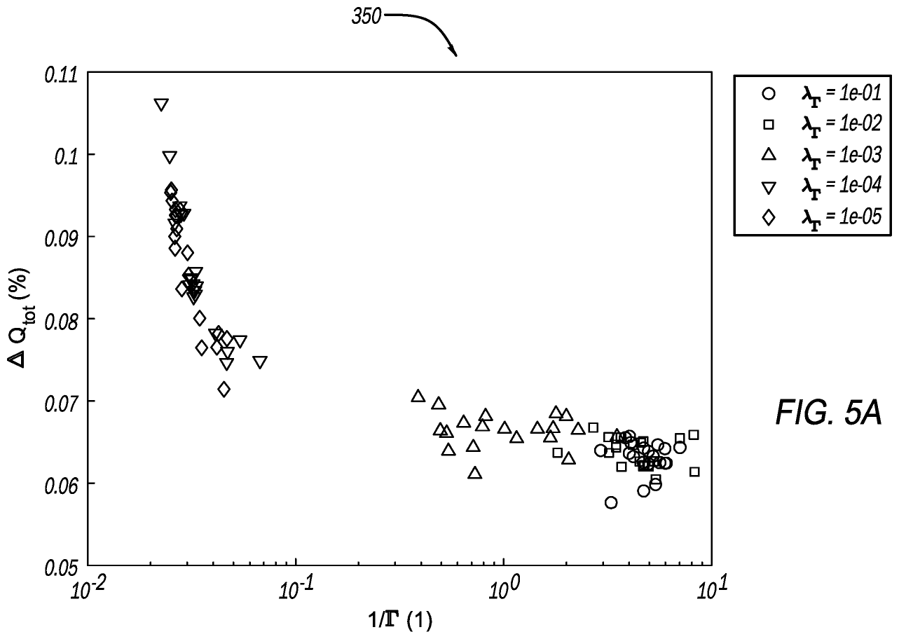

To test the procedure developed in terms of generating representative current profiles for accelerated battery aging studies, simulations were performed to evaluate the influence of a weight factor λ_{Γ} prioritizing capacity loss (leading to longer synthetic cycle duration) or similarity to the original dataset in terms of the feature matrix (leading to shorter duration of the synthetic cycle). FIGS. 5A and 5B illustrate sample results 350 from a Pareto analysis that was performed to explore the influence of λ_{Γ} on the solution of the GA. The parameters 360 of the simulation are summarized in FIG. 5B. For each value of λ_{Γ} GA is repeated 20 times to provide an estimate of the variability obtained on the solution. The multi-step method is utilized to improve the consistency of the solution.

While the points in the plot shown in FIG. 5A show moderate scatter on the respective plane due to the impact of variability in the solution of GA, a clear trade-off can be observed between the two separate objectives with respect to the weight. The analysis further suggests that significant differences in the trade-off between the two objectives lie only in the range λ_{Γ}ϵ[1e⁻⁴, 1e⁻²], without much sensitivity outside of the bounds.

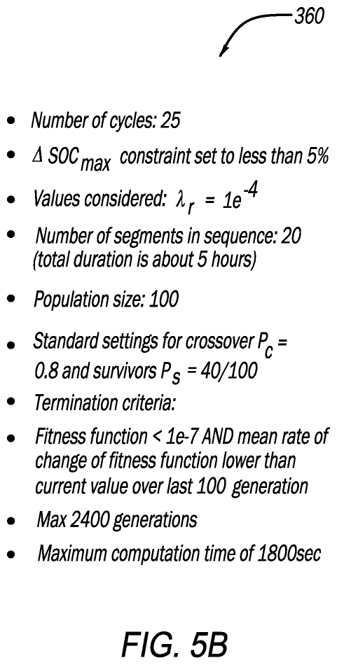

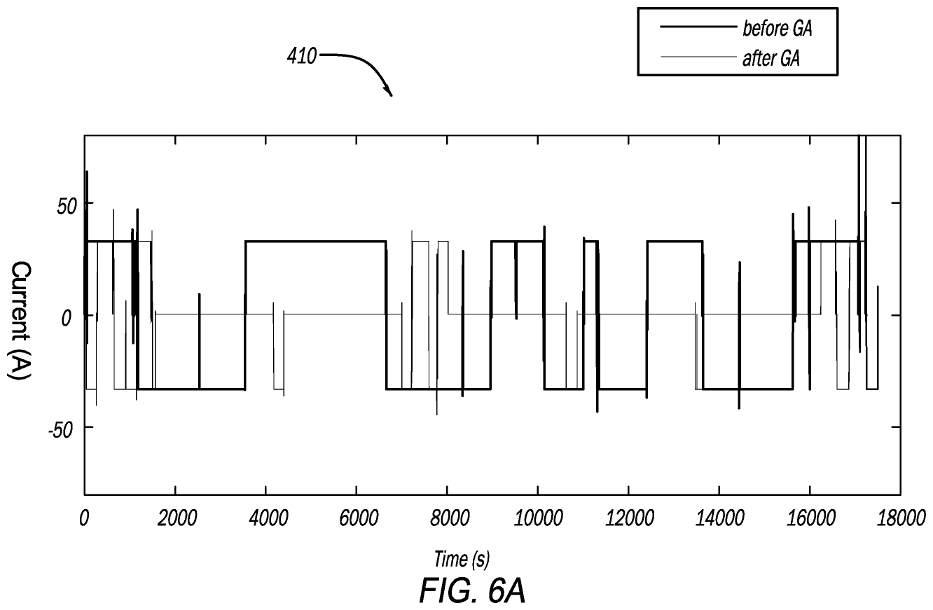

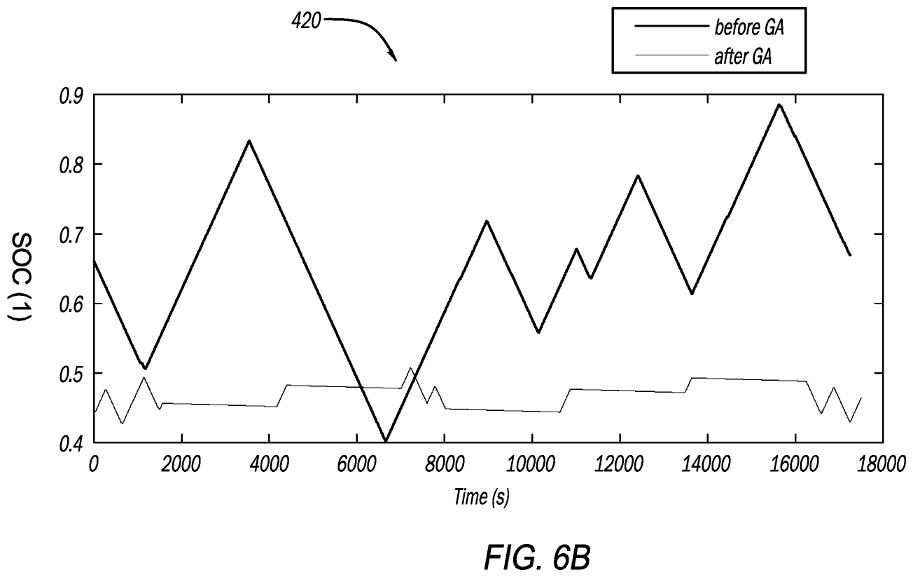

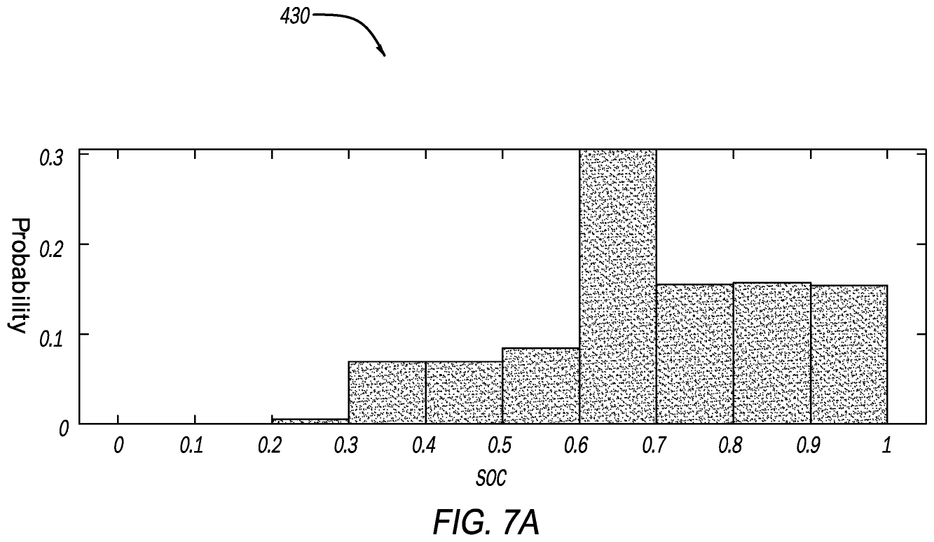

To generate a representative current profile, the procedure was executed for 20 segments, setting λ_{Γ}=1e⁻⁴, which prioritizes capacity loss as shown in FIG. 5A. The current and SOC behavior in time domain for the initial candidate profile and after executing the GA optimization are summarized at 410 and 420 respectively in FIGS. 6A and 6B. The SOC gap constraints between neighboring segments and the upper bound of the profile duration play an important role in determining the total capacity fade of the profile. As a result, the distribution of SOC values after optimization shown at 440, FIG. 7B with GA does not match the original distribution shown at 430, FIG. 7A. As can be appreciated, relaxation of constraints may improve the correlation.

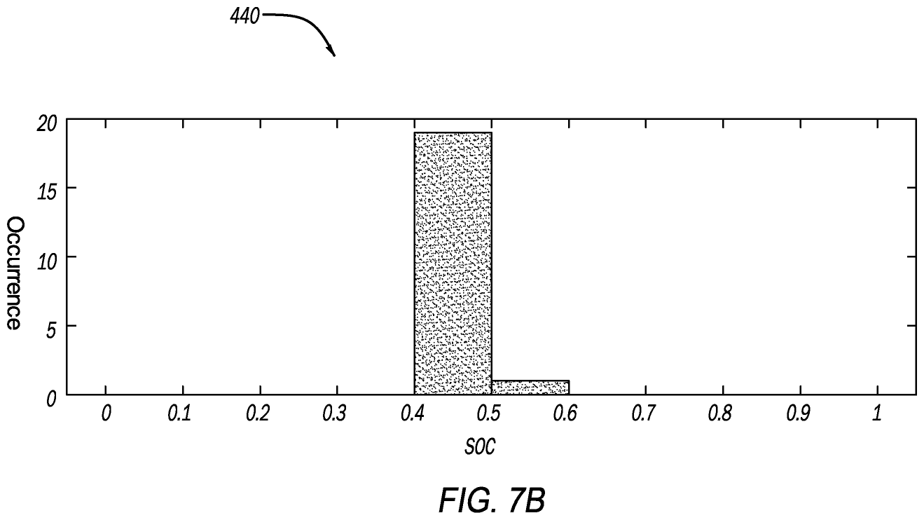

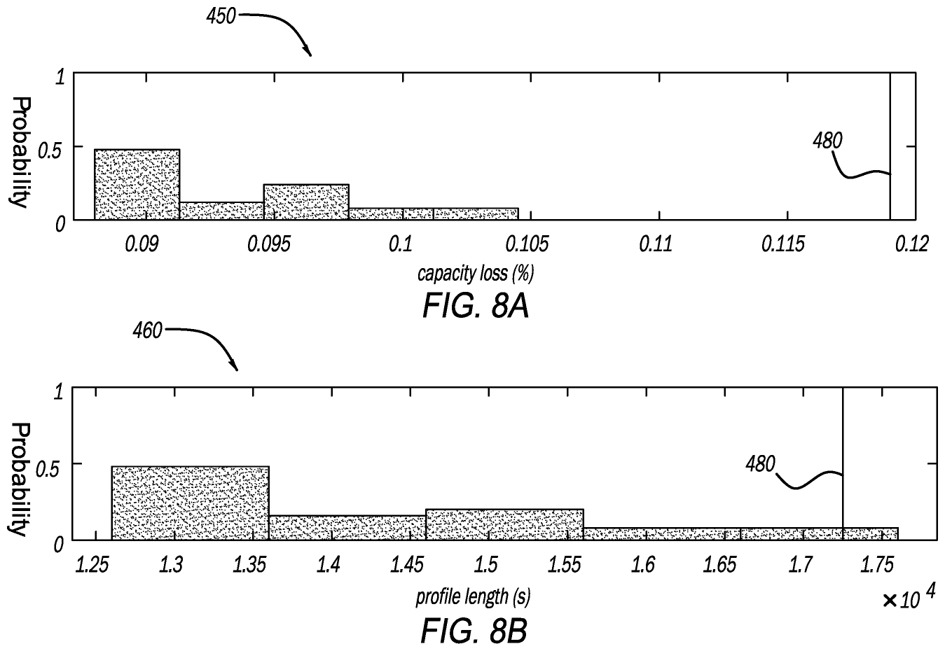

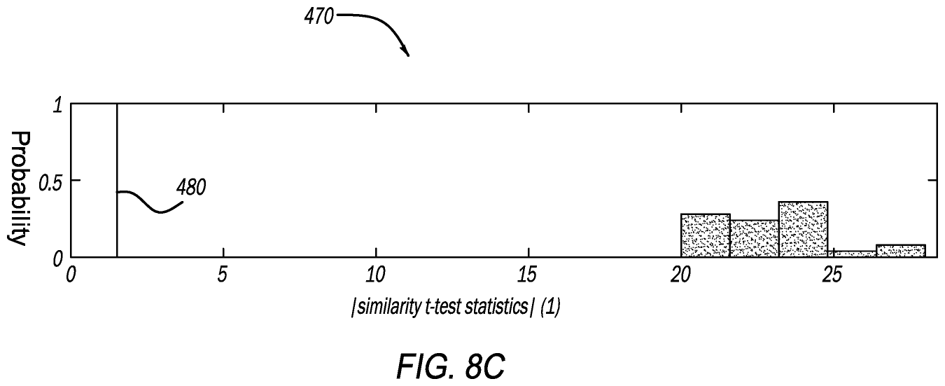

FIGS. 8A-8C illustrate summaries of 25 representative cycles generated using the GA based optimization algorithm. The distributions of capacity loss (%) 450, time duration of the profile(s) 460, and the similarity index 470 quantified by t-test statistics are compared against the corresponding values computed for the initial guess identified at line 480. Notably, the initial profile has higher capacity fade compared to all of the optimized profile. This is due to two reasons. First, the initial profile generated has a longer duration, nearly the longest duration compared to the other optimized profiles as shown at FIG. 8B. Second, the initial profile does not satisfy the constraints imposed on the maximum duration and minimum ΔSOC across adjacent segments. In summary, GA produces solutions with expected behavior. Relaxing the constraint on maximum SOC variation will likely improve the quality of the results, producing synthetic cycles while improving degradation and similarity.

The instant disclosure provides a physics-based model that considers the profile provided with all data from the original dataset obtained at 220. The model/algorithm can simulate how the battery 130 behaves and ages. By simulating this model, the optimization performed at 230 and 234 searches all of the original dataset provided at 220 and selects the portions of data (from the whole subset) that are mostly representative of the original set of usage data while at the same time causes the maximum degradation of the battery 130. The logic supporting the model/algorithm is based on the fact that a majority of time (for example, 75-95%) the vehicle is being used, the battery 130 is under minimal stress. In other words, the battery 130 will not be impacted negatively in terms of degradation. The remaining time, the battery 130 is under stress that can negatively impact the battery 130. The segments of data representative of the minimal stress events are substantially removed (deemphasized or filtered out) from the testing cycle. As a result, the time needed for a testing cycle is shortened. In this regard, portions of the data from the dataset are removed that are not significant for battery aging and the model/algorithm focuses on the data from the dataset that is significant for real world use but are more impactful for degradation of the battery 130.

At the optimization and verification steps 230, 234 (or subsequent to), a verification process is performed at 238. A synthetic profile of fixed duration is created and repeated for simulation using the original dataset at 220. For example, if the dataset 220 represents a year of data, the simulation can be performed relatively quickly (such as minutes or hours). The accelerated profile can be simulated to determine how much the accelerated profile has degraded the battery 130 (compared to the original set of data). In other examples, as preferred by the instant method, the accelerated cycle is simulated up to the point the battery 130 has reached the same amount of degradation as the original dataset 220 (in this example, one year of use). Comparing the duration of real world versus the synthetic cycle, a determination can be made as to how quickly the testing can be accelerated. The test can then be executed, such as in a lab, to obtain a multiplication factor. The multiplication factor can identify how long the testing will be needed (for example, three months) to simulate testing under the original dataset (prolonged one year testing).

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

Software includes instructions that are machine-readable and/or executable. Instructions may be logically grouped into programs, codes, methods, steps, actions, routines, functions, libraries, objects, classes, etc. Software may be stored by storage hardware or encoded in other hardware. Software encompasses (i) descriptive text to be parsed, such as HTML (hypertext markup language), XML (extensible markup language), and JSON (JavaScript Object Notation), (ii) assembly code, (iii) object code generated from source code by a compiler, (iv) source code for execution by an interpreter, (v) bytecode, (vi) source code for compilation and execution by a just-in-time compiler, etc. As examples only, source code may be written using syntax from languages including C, C++, JavaScript, Java, Python, R, etc.

Software also includes data. However, data and instructions are not mutually-exclusive categories. In various embodiments, the instructions may be used as data in one or more operations. As another example, instructions may be derived from data.

The functional blocks and flowchart elements in this disclosure serve as software specifications, which can be translated into software by the routine work of a skilled technician or programmer.

Software may include and/or rely on firmware, processor microcode, an operating system (OS), a basic input/output system (BIOS), application programming interfaces (APIs), libraries such as dynamic-link libraries (DLLs), device drivers, hypervisors, user applications, background services, background applications, etc. Software includes native applications and web applications. For example, a web application may be served to a device through a browser using hypertext markup language 5th revision (HTML5).

Software may include artificial intelligence systems, which may include machine learning or other computational intelligence. For example, artificial intelligence may include one or more models used for one or more problem domains.

Some or all of the software may run in a virtual environment rather than directly on hardware. The virtual environment may include a hypervisor, emulator, sandbox, container engine, etc. The software may be built as a virtual machine, a container, etc. Virtualized resources may be controlled using, for example, a DOCKER container platform, a pivotal cloud foundry (PCF) platform, etc.

In a client-server model, some of the software executes on first hardware identified functionally as a server, while other of the software executes on second hardware identified functionally as a client. The identity of the client and server is not fixed: for some functionality, the first hardware may act as the server while for other functionality, the first hardware may act as the client. In different embodiments and in different scenarios, functionality may be shifted between the client and the server. In one dynamic example, some functionality normally performed by the second hardware is shifted to the first hardware when the second hardware has less capability. In various embodiments, the term “local” may be used in place of “client,” and the term “remote” may be used in place of “server.”

Some or all of the software may be logically partitioned into microservices. Each microservice offers a reduced subset of functionality. In various embodiments, each microservice may be scaled independently depending on load, either by devoting more resources to the microservice or by instantiating more instances of the microservice. In various embodiments, functionality offered by one or more microservices may be combined with each other and/or with other software not adhering to a microservices model.

Some or all of the software may be arranged logically into layers. In a layered architecture, a second layer may be logically placed between a first layer and a third layer. The first layer and the third layer would then generally interact with the second layer and not with each other. In various embodiments, this is not strictly enforced—that is, some direct communication may occur between the first and third layers.

What is claimed is:

1. A method for designing an accelerated battery aging testing protocol from battery electric vehicle usage data, the method comprising:
creating an initial search space database based on a collection of vehicle usage data, the usage data including current demand over a first timeframe;
performing data compression including classifying the database into specific segments representing use events;
generating a synthetic profile including a sequence of elements having a battery current and a battery state of charge (SOC) for selected segments of the specific segments;
defining an optimization for accelerated aging of the battery; and
executing a genetic algorithm (GA) that generates the accelerated battery aging testing protocol requiring a second timeframe, shorter than the first timeframe, based on the optimization.

2. The method of claim 1, wherein the segments are selected proportionally to an amount of time the battery electric vehicle is used in all use events.

3. The method of claim 1, wherein the synthetic profile is statistically representative of the initial search space dataset.

4. The method of claim 1, wherein generating the synthetic profile for selected segments includes selecting segments representing high stress on the battery.

5. The method of claim 4, wherein generating the synthetic profile for selected segments includes removing segments representing low stress on the battery.

6. The method of claim 1, wherein generating the synthetic profile for selected segments includes selecting segments representative of driving conditions.

7. The method of claim 6, wherein generating the synthetic profile for selected segments includes selecting segments representative of rural driving conditions.

8. The method of claim 1, wherein generating the synthetic profile for selected segments includes selecting one of driving conditions and battery charging conditions.

9. The method of claim 1, wherein defining an optimization includes leveraging prediction of degradation of the battery resulting from applying a synthetic current sequence to a battery model.
